(19) United States
(12) Patent Application Publication
(10) Pub. No.: US 2008/0276983 A1
(43) Pub. Date: Nov. 13, 2008

(54) Encapsulation of Photovoltaic Cells

(76) Inventors: Robert Andrew Drake, Penarth (GB); Jean da la Croix Habimana, Morlanwelz (BE); Nick Evan Shephard, Midland, MI (US); Mustafa Mohamed, Midland, MI (US); Barry Mark Ketola, Freeland, MI (US); James Steven Tonge, Sanford, MI (US); Stephen Jenkins, Bay City, MI (US); Stephen Altum, Midland, MI (US)

Correspondence Address: DOW CORNING CORPORATION CO1232, 2200 W. SALZBURG ROAD, P.O. BOX 994, MIDLAND, MI, 48686-0994, US

(21) Appl. No.: 12/092,150

(22) PCT Filed: Nov. 3, 2006
(86) PCT No.: PCT/US06/43073

§ 371 Date: Apr. 30, 2008

Related U.S. Application Data
(60) Provisional application No. 60/733,684, filed on Nov. 4, 2005.

(51) Int. Cl. H01L 31/042

(52) U.S. Cl. 136/251

(57) ABSTRACT

This invention relates to a photovoltaic cell module and a process of applying a silicone based hot melt encapsulant material (102a, 104a) onto photovoltaic cells (103a) to form a photovoltaic cell module. There is provided a photovoltaic array with more efficient manufacturing and better utilization of the solar spectrum by using silicone hot melt sheets (102a, 104a) to give a silicone encapsulant photovoltaic device with the process ease of an organic encapsulant but the optical and chemical advantages of a silicone encapsulant. There is further provided a method for fabricating photovoltaic cells with increased throughput and optical efficiency when compared to prior art encapsulation methods. The preferred silicone material is provided in flexible sheet with hot melt properties and low surface tack.

This application claims the benefit of U.S. Provisional Patent Application Ser. No. 60/733,684, filed on 4 Nov. 2005, under 35 U.S.C. §119(e). U.S. Provisional Patent Application Ser. No. 60/733,684 is hereby incorporated by reference.

This invention was made with Government support under NREL Subcontract No. ZAX-5-33628-02, Prime Contract No: DE-AC36-98GO10337 awarded by the Department of Energy. The Government has certain rights in this invention.

### TECHNICAL FIELD OF THE INVENTION

This invention relates to a photovoltaic cell module and a process of applying a silicone based encapsulant material onto photovoltaic cells to form a photovoltaic cell module.

### BACKGROUND OF THE INVENTION

Solar or photovoltaic cells are semiconductor devices used to convert light into electricity (referred to hereafter as photovoltaic cells). Typically upon exposure to light, a photovoltaic cell generates a voltage across its terminals resulting in a consequent flow of electrons, the size of which is proportional to the intensity of the light impinging on the photovoltaic junction formed at the surface of the cell. There are generally currently two types of photovoltaic cells, wafers and thin films. A Wafer is a thin sheet of semiconductor material made by mechanically sawing it from a single crystal or multicrystal ingot or casting. Thin film based photovoltaic cells are continuous layers of semi-conducting materials typically deposited on a substrate or superstrate using sputtering or chemical vapour deposition processes or like techniques.

Because of the fragile nature of both wafer and thin film based photovoltaic cells, it is essential for the cells to be supported by a load carrying supporting member. The supporting member of the photovoltaic cell module may be a top layer (superstrate) which is transparent to sunlight i.e. positioned between the photovoltaic cells and a light source. Alternatively, the supporting member may be a back layer (substrate) which is positioned behind the photovoltaic cells. Often photovoltaic cell modules comprise both a superstrate and a substrate. Each of the substrate and superstrate may be rigid, e.g. a glass plate, or a flexible material e.g. a metallic films and/or sheets or suitable plastic materials such as polyimides, although the choice of material for superstrates is restricted by their need to be transparent to sunlight.

A solar or photovoltaic cell module (hereafter referred to as a photovoltaic cell module) comprises a single photovoltaic cell or a planar assembly (an array) of electrically interconnected photovoltaic cells on a superstrate and/or substrate as hereinbefore described. The cells are generally adhered to the superstrate and/or substrate using an encapsulant or barrier coating material (Hereafter referred to as “encapsulant(s)”). The encapsulant is used to generally protect the cells from the environment (e.g. wind, rain, snow, dust and the like and in accordance with general current practise is used to both encapsulate the cells and laminate them to the substrate and/or superstrate to form an integral photovoltaic cell module.

Typically a series of photovoltaic cell modules are interconnected to form a solar array which functions as a single electricity producing unit wherein the cells and modules are interconnected in such a way as to generate a suitable voltage in order to power a piece of equipment or supply a battery for storage etc.

Usually wafer based photovoltaic cell modules are designed using a superstrate usually in combination with a substrate and having one or more layers of encapsulant as a cell adhesive for adhering the cells to the superstrate and when present to the substrate. Hence, light passes through the transparent superstrate and encapsulant/adhesive before reaching the semi-conducting wafer.

In many instances, several layers of encapsulant may be applied using either the same or different encapsulant materials for different layers. For example a module may comprise a superstrate (e.g. glass) supporting a plurality of photovoltaic cells with a first layer of an organic encapsulant e.g. ethyl vinyl acetate (EVA) which is transparent to sunlight, utilised as an adhesive, to adhere the superstrate to a series of interconnected photovoltaic cells. A second or rear layer of encapsulant may then be applied onto the first layer of encapsulant and interconnected photovoltaic cells. The second layer of encapsulant may be an additional layer of the same material as used for the first encapsulant, and/or may be transparent or any suitable colour.

The superstrate, typically a rigid panel, serves to protect one side of the photovoltaic cell from potentially harmful environmental conditions and the other side is protected by the combination of several layers of encapsulants and a substrate. A wide variety of materials have been proposed for use as photovoltaic cell module encapsulants. Common examples include films of ethylene-vinyl acetate copolymer (EVA), Tedlar® from E.I. Dupont de Nemours & Co of Wilmington Del. and UV curable urethanes. The encapsulants are generally supplied in the form of films and are laminated to the cells, superstrate and/or substrate. Prior art examples include the lamination of photovoltaic cells using adhesives as exemplified in U.S. Pat. No. 4,331,494 and the application of an acrylic polymer and a weather resistant layer as described in U.S. Pat. No. 4,374,955. Photovoltaic cell modules have also been prepared by casting and curing acrylic prepolymers onto the photovoltaic cells as described in U.S. Pat. No. 4,549,033.

The substrate, when present, is in the form of a rigid or stiff backskin which is designed to provide protection to the rear surface of the module. A wide variety of materials have been proposed for the substrate, which does not necessarily need to be transparent to light, these include the same materials as the superstrate e.g. glass but may also include materials such as organic fluoropolymers such as ethylene tetrafluoroethylene (ETFE), Tedlar®, or poly ethylene terephthalate (PET) alone or coated with silicon and oxygen based materials (SiOₓ).

One problem with photovoltaic cell modules currently used in the industry is the fact that organic based thermoplastic materials used as encapsulants to laminate photovoltaic cell modules are well known to have poor adhesive properties relative to glass. This problem whilst not always initially evident often leads to gradual delamination of a thermoplastic layer from glass surfaces in a photovoltaic cell module over periods of prolonged weathering. This delamination process results in several negative effects on cell efficiency; such as it causes water accumulation in the encapsulant ultimately resulting in cell corrosion. Laminates prepared using these organic based thermoplastic materials also have a low UV resistance and as such discolour, generally turning yellow or brown over the lifetime of a photovoltaic cell, leading to a non-aesthetically pleasing module. Typically, a substantial amount of adhesive may often be required to reduce delamination effects and UV screens need to be incorporated in the module to decrease long-term discolouration when such materials are used as the encapsulant. Such UV screens necessarily reduce the total available light impinging on the solar cell by adsorbing the UV wavelengths, thereby reducing cell efficiency.

For wafer type solar modules e.g. crystalline silicon wafer modules, one of the main problems is the cost of the materials used; for example, the substrate material is generally expensive. There are two widely used substrate materials, both of which tend to be expensive: EVA laminate and Tedlar®, referred to above, a polyvinyl fluoride (PVF) and the other widely used substrate material is glass in glass/cell/glass configuration. As previously discussed the substrate may also comprise organic fluoropolymers such as ethylene tetrafluoroethylene (ETFE), or poly ethylene terephthalate (PET) alone or coated with silicon and oxygen based materials (SiOₓ). It is also known that the cost of the encapsulant and the substrate materials, when required, represent a substantial fraction of the overall cost of each cell and/or module.

Historically the first photovoltaic arrays produced in the early 1970's used liquid silicone to protect the cells. However whilst the long term durability of these encapsulated photovoltaic arrays has proven to be excellent, the materials and methods used for encapsulation provided the user with many problems including:—

i. The silicone was very expensive;

ii. The process required damming and filling a two part material; and

iii. Film thickness was difficult to control These problems proved seemingly insurmountable at the time and the market moved to ethyl vinyl acetate (EVA) resin encapsulants which are still used today (in the form of EVA sheet resins).

Current best practices typically involve the application of a thermosetting EVA organic polymer sheet. Depending on the type of photovoltaic cell being encapsulated (i.e. rigid or flexible, crystalline or amorphous) one or multiple sheets of EVA are sandwiched, under a transparent superstrate then the entire assembly is subject to heat, vacuum and pressure where upon the EVA flows, wets and reacts to form a clear protective layer. EVA sheet resins are cured by peroxide which can promote side reactions that reduce EVA durability in use.

EVA is currently limited to radical curing processes involving laminator temperatures in the region of between 150 and 160° C. Such low temperatures are used in order to prevent excessive stress in the fragile photovoltaic cells, and generally costly wear and tear on the laminating machines. Few radical initiating species are readily available with half-lives suitable to give sufficient degrees of cure while maintaining adequate shelf-life.

EVA has the required physical properties in the visible light spectrum. It is however, degraded by wavelengths below 400 nm. Hence current EVA based modules are limited to harvesting light at wavelengths above 400 nm. In order to protect the EVA, special glass typically doped with cerium is necessary. Alternatively, a UV stabilizing package involving UV absorbers or hindered amine light stabilizers are used. This represents 1 to 5% loss in efficiency.

A variety of encapsulants have been proposed which contain silicon based materials. JP09-064391 describes the use of phenyl containing silicone resin for adhesive encapsulation layers for photovoltaic cells. U.S. Pat. No. 5,650,019 discusses the provision of adhesive layers for thin film photovoltaic cells and methods of providing suitably robust encapsulation. In this case a fluorocarbon based superstrate is utilised. Again the nature of the silicone resin is not detailed. U.S. Pat. No. 6,204,443 describes a multi-layer (typically 3 or more layers) encapsulation system which may be applied to a glass. U.S. Pat. No. 6,706,960 describes an adhesive layer between the superstrate and photovoltaic cells made from a phase separating blend of two polymers one of which can be siloxane and advocates that it has the advantage of increase light incidence on the photovoltaic cell over the prior art.

JP09-132716 describes the use of siloxane high consistency rubber (HCR) protective sheets to provide a photovoltaic cell module superior in transparency, flame retardant property, weatherability and moldability. JP10-321888, JP10-321887 and JP10-321886 propose methods to reduce tack by applying inorganic, organic or silicon resin to the surface. EP0042458 describes a Photovoltaic cell module comprising a superstrate which may comprise a transparent silicone elastomer. U.S. Pat. No. 4,057,439 describes a solar panel having photovoltaic cells adhered to the base surface thereof by a single component, room temperature vulcanizing silicone resin and encapsulated in a multicomponent silicone resin.

U.S. Pat. No. 4,116,207 describes a solar panel including photovoltaic cells encapsulated in a silicone resin, in which the base member to which the silicone resin adheres is a glass mat polyester in laminate or molded form. U.S. Pat. No. 4,139,399 describes a Solar panel formed using a frame defining channels adapted to receive and retain a solid body of resin therein. The body of resin forms a matrix that encapsulates photovoltaic cells.

Whilst the applicant's co-pending application, WO 2005/006451, describes a composition and method for a continuous encapsulation process using liquid based encapsulant materials, typically existing methods for photovoltaic cell module encapsulation are usually carried out in a batch mode because of the need for one or more lamination steps.

The limited availability of hydrocarbon fuel sources is driving the expansion of the photovoltaic cell industry. The use of photovoltaic cells for generating electricity still only has a relatively low market share, at least partially because of the initial high cost of the photovoltaic cell array. Therefore, there is an industrial need for improvements in photovoltaic cell array assembly speed and final cell efficiency.

### SUMMARY OF THE INVENTION

In accordance with a first aspect of the present invention there is provided a photovoltaic cell module comprising a photovoltaic cell or an array of photovoltaic cells encapsulated in an organopolysiloxane based hot melt material, said organopolysiloxane based hot melt material being adhered to a light transparent superstrate and optionally to a supporting substrate.

For the sake of this invention an array of photovoltaic cells is series of interconnected photovoltaic cells.

“Hot melt” materials may be reactive or unreactive. Reactive hot melt materials are chemically curable thermoset products which are inherently high in strength and resistant to flow (i.e. high viscosity) at room temperature. The viscosity of hot melt materials tend to vary significantly with changes in temperature from being highly viscous at relatively low temperatures (i.e. at or below room temperature) to having comparatively low viscosities as temperatures increase towards 200° C. Compositions containing reactive or non-reactive hot melt materials are generally applied to a substrate at elevated temperatures (i.e. temperatures greater than room temperature, typically greater than 50° C.) as the composition is significantly less viscous at elevated temperatures (e.g. 50 to 200° C.) than at room temperature or thereabouts. Typically hot melt materials are applied on to substrates at elevated temperatures as flowable masses and are then allowed to quickly “resolidify” merely by cooling, however in the present invention an alternative process namely the application of sheets of hot melt material are initially applied at room temperature and are heated in the presence of the one or more photovoltaic cells and/or the superstrate and optionally the substrate with a view to adhering same together to form the required module.

Such hot melt materials are designed to provide a sufficient green strength for applications requiring strong initial bonds between the hot melt material, the photovoltaic cell(s), superstrate and optionally substrate.

It is to be understood that “Green strength” as referred to above is the bond strength prior to completion of chemical cure of the organopolysiloxane component by e.g. any one of cure systems described below.

In accordance with a further aspect of the present invention there is provided a method for fabricating photovoltaic cell modules comprising the steps of
i) bringing at least one sheet of organopolysiloxane based hot melt material into contact with
   (a) a photovoltaic cell or an array of photovoltaic cells and/or
   (b) a light transparent superstrate;

at room temperature;
ii) heating the combination resulting from step (i) such that the sheet(s) of organopolysiloxane based hot melt material become(s) a liquid of sufficiently low viscosity to adhere to said photovoltaic cell(s) and/or to said superstrate;
iii) allowing the product resulting from step (ii) to cool;
iv) bringing the product of step (iii) into contact with either (a) or (b) when omitted from step (i) and/or optionally a substrate and reheating and cooling to form a photovoltaic cell module.

Step (iv) may take place during or subsequent to step (iii) but preferably occurs at a temperature above room temperature. If required the product of step (iii) may be reheated during step (iv) to enhance the green strength of the encapsulant.

Preferably the sheets in accordance with the present invention are non tacky at room temperature and/or prior to heating, thereby avoiding potential handling problems involved in the application of tacky sheets. Sheets may be applied prior to cure manually or by any other suitable means e.g. by robot. The sheets require sufficient strength to ensure that they do not stretch and/or tear during application. The sheets may be provided for use either uncured or partially cured.

In one embodiment of the present invention there is provided a method of encapsulating a photovoltaic cell or an array of photovoltaic cells using sheets of organopolysiloxane based hot melt materials which are initially applied to a photovoltaic cell or an array of photovoltaic cells and then the resulting encapsulated photovoltaic cell or an array of photovoltaic cells are applied onto the superstrate. Alternatively there is provided a method of encapsulating photovoltaic arrays using sheets of organopolysiloxane based hot melt materials which are initially applied to the superstrate e.g. glass and then a cell is applied on to the pre-coated superstrate, e.g. glass.

A method in accordance with the present invention will provide increased throughput and optical efficiency when compared to prior art encapsulation methods due to the simplicity of the process utilised by using a one component silicone hot melt sheet which is tack free and processes at comparably faster speeds, equal or lower laminating temperatures to existing organic EVA encapsulants. The resulting product provides improved cell efficiency by utilizing UV sensitive cells in combination with light transparent superstrate and light transparent silicone.

In accordance with a still further aspect of the present invention there is provided a process for the manufacture of a sheet of an organopolysiloxane based hot melt material.

Any suitable organopolysiloxane based hot melt material may be utilised provided it is formable into sheets prior to curing. Preferably however the organopolysiloxane based hot melt material is a reactive organopolysiloxane based hot melt material. One very important advantage in using the flexible sheets made from a reactive silicone hot-melt encapsulant formulation is that it is possible to cure the encapsulant into a network formation which can be achieved via several routes using silicone cure chemistries. Depending on the reactive functionalities incorporated, cure can be affected via moisture, heat or radiation.

In one embodiment of the present invention the organopolysiloxane based hot melt material is made from sheets made by blending suitable silicone polymers with resins most preferably silicone resins and therefore may be prepared by blending a preferably substantially linear organopolysiloxane polymer and silicone resin for low cost and easy handling. The resulting hot melt materials are preferably reactive such that the sheets are curable when in contact with the photovoltaic cell(s), superstrate and optionally substrate. Whilst non-reactive physical blends of silicone polymer and resin have some utility, they will, with cyclic heating and cooling, eventually result in deleterious flow and creep of the resulting encapsulant and as such are not preferred.

Hence, whereas it is not essential typically both the polymer and resin will comprise sterically unhindered reactive groups which are adapted to interact in the presence of an initiator or catalyst/cross linker system.

In the case of this embodiment of the invention a flexible sheet of organopolysiloxane based (silicone) material used as an encapsulant in accordance with the invention preferably comprises:

Component (A) A high molecular weight diorganopolysiloxane also referred as silicone gum having at least two reactive groups per molecule, which reactive groups are designed to cure with component B where possible;
Component (B) a silicone resin (MDTQ) or mixture of resins. The resin(s) may or may not contain groups that could possibly react with component (A); and
Component (C) a suitable curing package which is chosen to cure the interactive groups between components A and B, typically the cure system is chosen from the most appropriate curing package(s).

Component (A) is preferably a diorganopolysiloxane represented by the following average unit formula:

(R′₃SiO_{1/2})x(R′₂SiO_{2/2})y(R′SiO_{3/2})z

wherein: x and y are positive numerical values and z is 0 or a positive numerical value with the provisos that x+y+z is at least 700 but is preferably greater than 10 000, y/(x+y+z) is greater than or equal to 0.8, more preferably greater than or equal to 0.95; and each R′ may be the same or different and is a monovalent radical independently selected from the group consisting of alkyl groups such as methyl, ethyl, propyl, isopropyl, butyl, tertiary butyl, phenyl groups or alkylphenyl groups, hydrogen, hydroxyl, alkenyl, alkoxy, oximo, epoxide, carboxyl, and alkyl amino radicals Preferably at least two R′ groups per molecule are reactive groups. Preferred reactive groups are unsaturated groups such as alkenyl and/or alkynyl groups, but are most preferably alkenyl groups. Preferably, component (A) has a viscosity at 25° C. of preferably greater than 1 000 000 mPa·s, (i.e. having a gum like consistency) and a molecular structure which is substantially linear although may be partially branched. The polymer may additionally contain reactive groups other than unsaturated groups. Particularly preferred additional reactive groups are alkoxy groups and/or epoxy groups the presence of which enhances the adhesion properties of the resulting sheets to the other constituents of the module.

Generally, such stiff gum-like polymers have a degree of polymerisation (dp) of above about 1500 and due to their viscous nature are generally referred to in terms of Williams plasticity numbers (typically using ASTM D926) because of the problem in measuring such high viscosities. The Williams plasticity numbers for such gums are typically in the range of from about 30 to 250 (using ASTM D926), and preferably from 95 to 125. The plasticity number, as used herein, is defined as the thickness in millimeters ×100 of a cylindrical test specimen 2 cm³ in volume and approximately 10 mm in height after the specimen has been subjected to a compressive load of 49 Newtons for three minutes at 25° C.

Examples of component (A) comprising alkenyl reactive groups such as vinyl, propenyl, butenyl, hexenyl and the like might include

a dimethylalkenylsiloxy-terminated dimethylpolysiloxane,
a dimethylalkenylsiloxy-terminated copolymer of methylalkenylsiloxane and dimethylsiloxane,
a dimethylalkenylsiloxy-terminated copolymer of methylphenylsiloxane and dimethylsiloxane,
a dimethylalkenylsiloxy-terminated copolymer of methylphenylsiloxane, methylalkenylsiloxane, and dimethylsiloxane,
a dimethylalkenylsiloxy-terminated copolymer of diphenylsiloxane and dimethylsiloxane,
a dimethylalkenylsiloxy-terminated copolymer of diphenylsiloxane, methylalkenylsiloxane, and dimethylsiloxane, or any suitable combination of the above.
Most preferably each alkenyl group in component (A) is a vinyl or hexenyl group.

When the polymer comprises hydroxy or hydrolysable groups which may or may not be terminal groups, provided that they are sterically unhindered wherein the polymer is a polysiloxane based polymer containing at least two hydroxyl or hydrolysable groups, most preferably the polymer comprises terminal hydroxyl or hydrolysable containing groups X and X¹ which may be the same or different as will be described further below. For example in the case where the polymer has the general formula

X-A-X¹

X and X¹ are independently selected and terminate in hydroxyl or hydrolysable groups and A is a siloxane molecular chain.

X and/or X¹ may for example terminate with any of the following groups —Si(OH)₃, —(R^{a})Si(OH)₂, —(R^{a})₂SiOH, —R^{a}Si(OR^{b})₂, —Si(OR^{b})₃, —R₂^{a}SiOR^{b} or —R₂^{a}Si —R^{c}— SiRₚ^{d}(OR^{b})₃₋ₚ where each R^{a} independently represents a monovalent hydrocarbyl group, for example, an alkyl group, in particular having from 1 to 8 carbon atoms, (and is preferably methyl); each R^{b} and R^{d} group is independently an alkyl or alkoxy group in which the alkyl groups suitably have up to 6 carbon atoms; R^{c} is a divalent hydrocarbon group which may be interrupted by one or more siloxane spacers having up to six silicon atoms; and p has the value 0, 1 or 2.

Suitably, X and/or X¹ contain groups which are hydrolysable in the presence of moisture.

Examples of suitable groups A in the above formula are those which comprise a polydiorgano-siloxane chain. Thus group A preferably includes siloxane units of the following formula

—(Rₛ⁵SiO_{(4-s)/2})—

in which each R⁵ is independently an organic group such as a hydrocarbyl group having from 1 to 10 carbon atoms optionally substituted with one or more halogen group such as chlorine or fluorine and s is 0, 1 or 2. Particular examples of groups R⁵ include methyl, ethyl, propyl, butyl, vinyl, cyclohexyl, phenyl, tolyl group, a propyl group substituted with chlorine or fluorine such as 3,3,3-trifluoropropyl, chlorophenyl, beta-(perfluorobutyl)ethyl or chlorocyclohexyl group. Suitably, at least some and preferably substantially all of the groups R⁵ are methyl. Preferably there are at least approximately 700 units of the above formula per molecule.

Component (B) may be an organosiloxane resin such as MQ resins containing R₃⁵SiO_{1/2} units and SiO_{4/2} units; TD resins containing R⁵SiO_{3/2} units and R₂⁵SiO_{2/2} units; MT resins containing R₃⁵SiO_{1/2} units and R⁵SiO_{3/2} units; MTD resins containing R₃⁵SiO_{1/2} units, R⁵SiO_{3/2} units, and R₂⁵SiO_{2/2} units, or combinations thereof (where R⁵ is as described above).

The symbols M, D, T, and Q used above represent the functionality of structural units of polyorganosiloxanes including organosilicon fluids, rubbers (elastomers) and resins. The symbols are used in accordance with established understanding in the silicone industry. M represents the monofunctional unit R₃⁵SiO_{1/2}; D represents the difunctional unit R₂⁵SiO_{2/2}; T represents the trifunctional unit R⁵SiO_{3/2}; and Q represents the tetrafunctional unit SiO_{4/2}. The structural formula of these units is shown below.

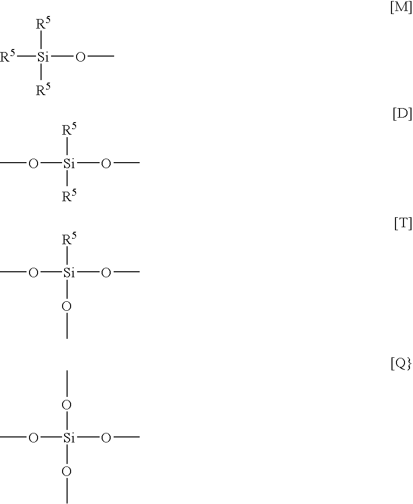

Preferably the ratio of resin to gum is from 1:1 to 9:1, most preferably between 1.5:1 to 3:1. Preferably the molecular weight of the resin is at least 5000, preferably greater than 10000.

Silicone resins of this type impart outstanding UV resistance to the encapsulant and therefore there is no need for the inclusion of one or more UV screen additives which in the case of most prior art formulations was typically essential. Furthermore, cerium doped glass is likewise not necessary. The cured organopolysiloxane hot melt material resulting from the sheets used in accordance with the present invention exhibit long term UV & visual light transmission thereby allowing the maximum amount of light to reach solar cells.

As previously discussed preferably the hot melt material used is a reactive hot melt which comprises a suitable cure package, dependent on the reactive nature of the other components in the composition. The following identified as component (C)(i) to (C)(iv) is a list of alternative suitable curing packages which may be chosen to cure the hot melt composition. The ideal cure package used for the respective purpose is determined in view of the reactive groups present in components (A) and (B) of the composition.:—

### Component (C)(i)

This component is utilised when components A and B both contain two or more alkenyl groups) and comprises a hydrosilylation catalyst in combination with a cross-linking agent in the form of a polyorganosiloxane having at least two silicon-bonded hydrogen atoms per molecule. A hydrosilylation or addition cure reaction is the reaction between an Si—H group (typically provided as a cross-linker) and an Si-alkenyl group, typically a vinyl group, to form an alkylene group between adjacent silicon atoms (≡Si—CH₂—CH₂—Si≡.

Preferably the catalyst of Component (C)(i) is a hydrosilylation (i.e. addition cure type) catalyst may comprise any suitable platinum, rhodium, iridium, palladium or ruthenium based catalyst. However preferably the catalyst in component (C)(i) is a platinum based catalyst. The platinum-based catalyst may be any suitable platinum catalyst such as for example a fine platinum powder, platinum black, chloroplatinic acid, an alcoholic solution of chloroplatinic acid, an olefin complex of chloroplatinic acid, a complex of chloroplatinic acid and alkenylsiloxane, or a thermoplastic resin that contain the aforementioned platinum catalyst. The platinum catalyst is used in an amount such that the content of metallic platinum atoms constitutes from 0.1 to 500 parts by weight per 1,000,000 parts by weight of component (A).

The cross-linking agent of component (C)(i) may be in the form of a polyorganosiloxane having at least two silicon-bonded hydrogen atoms per molecule and has the following average unit formula:

R_{b}ⁱSiO_{(4-b)/2}

where each Rⁱ may be the same or different and is hydrogen, an alkyl group such as methyl, ethyl, propyl, and isopropyl or an aryl group such as phenyl and tolyl. Component (C) may have a linear, partially branched linear, cyclic, or a net-like structure.

Examples of the aforementioned organopolysiloxane include one or more of the following:—

a trimethylsiloxy-terminated polymethylhydrogensiloxane,
a trimethylsiloxy-terminated copolymer of methylhydrogensiloxane and dimethylsiloxane,
a dimethylhydrogensiloxy-terminated copolymer of methylhydrogensiloxane and dimethylsiloxane,
a cyclic polymer of methylhydrogensiloxane,
a cyclic copolymer of methylhydrogensiloxane and dimethylsiloxane,
an organopolysiloxane composed of siloxane units expressed by the formula (CH₃)₃SiO_{1/2}, siloxane units expressed by the formula (CH₃)₂HSiO_{1/2}, and siloxane units expressed by the formula SiO_{4/2},
an organopolysiloxane composed of siloxane units expressed by the formula (CH₃)₂HSiO_{1/2}, siloxane units expressed by the formula CH₃SiO_{3/2},
an organopolysiloxane composed of siloxane units expressed by the formula (CH₃)₂HSiO_{1/2}, siloxane units expressed by the formula (CH₃)₂SiO_{2/2}, and siloxane units expressed by the formula CH₃SiO_{3/2},
a dimethylhydrogensiloxy-terminated polydimethylsiloxane,
a dimethylhydrogensiloxy-terminated copolymer of methylphenylsiloxane and dimethylsiloxane, and
a dimethylhydrogensiloxy-terminated copolymer of a methyl (3,3,3-trifluoropropyl) siloxane and dimethylsiloxane; or by using cyclic silicone hydride cross linkers as outlined in WO2003/093349 or WO2003/093369 (incorporated herein by reference).

It is recommended that cross-linking agent of component (C)(i) be added in an amount such that the mole ratio of silicon-bonded hydrogen atoms in the cross-linking agent (C)(i) to the mole number of alkenyl groups in components (A) and (B) is in the range of from 0.1:1 to 5:1, more preferably it is in the range of from 0.8:1 to 4:1. If the above ratio is lower than 0.1:1, the density of cross-linking will be too low and it will be difficult to obtain a rubber-like elastomer. A ratio having an excess of Si—H groups (i.e.>1:1) is preferred to enhance adhesion between the superstrate/substrate e.g. glass and the encapsulant.

When component (C)(i) is present the composition may also comprise one or more curing inhibitors in order to improve handling conditions and storage properties of the composition, for example acetylene-type compounds, such as 2-methyl-3-butyn-2-ol, 2-phenyl-3-butyn-2-ol, 3,5-dimethyl-1-hexyn-3-ol, 1-ethynyl-1-cyclohexanol, 1,5-hexadiene, 1,6-heptadiene; 3,5-dimethyl-1-hexen-1-yne; 3-ethyl-3-buten-1-yne and/or 3-phenyl-3-buten-1-yne; an alkenylsiloxane oligomer such as 1,3-divinyltetramethyldisiloxane, 1,3,5,7-tetravinyltetramethyl cyclotetrasiloxane, or 1,3-divinyl-1,3-diphenyldimethyldisiloxane; a silicon compound containing an ethynyl group such as methyltris (3-methyl-1-butyn-3-oxy) silane; a nitrogen-containing compound such as tributylamine, tetramethylethylenediamine, benzotriazole; a similar phosphorus-containing compound such as triphenylphosphine; as well as sulphur-containing compounds, hydroperoxy compounds, or maleic-acid derivatives.

The aforementioned curing inhibitors are used in an amount of from 0 to 3 parts by weight, normally from 0.001 to 3 parts by weight, and preferably from 0.01 to 1 part by weight per 100 parts by weight of component (A). Most preferable among the curing inhibitors are the aforementioned diallylmaleate-type compounds, which demonstrate the best balance between storage characteristics and speed of curing when they are used in a combination with aforementioned component (D).

### Component (C)(ii)

Component (C)(ii) consists of peroxide catalysts which are used for free-radical based reactions between siloxanes comprising:—

≡Si—CH₃ groups and other ≡S₁—CH₃ groups; or
≡S₁—CH₃ groups and ≡Si-alkenyl groups (typically vinyl); or
≡Si-alkenyl groups and ≡Si-alkenyl groups. For peroxide cure components A and B above would preferably be retained with a suitable peroxide catalyst and any or all of the additives described elsewhere (with the exception of the cure inhibitors which are specific to hydrosilylation type catalysis) may be utilised. Whilst this cure system would, because of its nature, cure otherwise unreactive polymer/resin blends the presence of some alkenyl groups, typically vinyl groups is preferred. For peroxide cure components A and B above would preferably be retained with a suitable peroxide catalyst and any or all of the additives described above may be utilised. Suitable peroxide catalysts may include but are not restricted to 2,4-dichlorobenzoyl peroxide, benzoyl peroxide, dicumyl peroxide, tert-butyl perbenzoate. 1,1-bis(t-butylperoxy)-3,3,5-trimethylcyclohexane (TMCH) (2,5-bis(t-butylperoxy)-2,5-dimethylhexane) catalyst1,1-bis(tert-amylperoxy)cyclohexane, Ethyl 3,3-bis(tert-amylperoxy)butyrate and 1,1-bis(tert-butylperoxy)cyclohexane, delivered as a neat compound or in an inert matrix (liquid or solid).

Component (C)(ii), is preferably present in an amount of from 0.01 to 500 parts by weight per 1,000,000 parts by weight of component (A)

When Component (C)(ii) i.e. one or more radical initiators is/are utilised the temperature at which the curing is initiated is generally determined/controlled on the basis of the half-life of the radical initiators, however the rate of cure and ultimate physical properties are controlled by the level of unsaturation. There are a large number of silicone species which can be used to achieve a critical level of unsaturation necessary for a given reaction profile. The reaction kinetics and physical properties can be tuned by blending, linear non-reactively endblocked polymers with differing degrees of polymerization (dp) with dimethylmethylvinyl-copolymers with or without vinyl endblocking.

(C)(iii) (utilised when components A and B both contain hydroxy and/or hydrolysable groups) a condensation catalyst in combination with one or more silanes or siloxane based cross-linkers which contain silicon bonded hydrolysable groups such as acyloxy groups (for example, acetoxy, octanoyloxy, and benzoyloxy groups); ketoximino groups (for example dimethyl ketoximo, and isobutylketoximino); alkoxy groups (for example methoxy, ethoxy, an propoxy) and alkenyloxy groups (for example isopropenyloxy and 1-ethyl-2-methylvinyloxy);

Resin polymer blends can be prepared such that they form a sheeting material that on exposure to a moist atmosphere reacts to form a permanent network. Material suitable for use in photovoltaic applications could be prepared by using alkoxy-functional silicone polymers with resins which are, or aren't, capable of co-reacting with the moisture triggered polymers.

(C)(iii) is a condensation catalyst in combination with one or more silanes or siloxane based cross-linkers which contain silicon bonded hydrolysable groups such as acyloxy groups (for example, acetoxy, octanoyloxy, and benzoyloxy groups); ketoximino groups (for example dimethyl ketoximo, and isobutylketoximino); alkoxy groups (for example methoxy, ethoxy, an propoxy) and alkenyloxy groups (for example isopropenyloxy and 1-ethyl-2-methylvinyloxy).

Any suitable condensation catalyst may be utilised to cure the composition these include condensation catalysts including tin, lead, antimony, iron, cadmium, barium, manganese, zinc, chromium, cobalt, nickel, aluminium, gallium or germanium and zirconium. Examples include organic tin metal catalysts such as alkyltin ester compounds such as Dibutyltin dioctoate, Dibutyltin diacetate, Dibutyltin dimaleate, Dibutyltin dilaurate, butyltin 2-ethylhexoate. 2-ethylhexoates of iron, cobalt, manganese, lead and zinc may alternatively be used but titanate and/or zirconate based catalysts are preferred. Such titanates and zirconates may comprise a compound according to the general formula Ti[OR]₄ and Zr[OR]₄ respectively, where each R may be the same or different and represents a monovalent, primary, secondary or tertiary aliphatic hydrocarbon group which may be linear or branched containing from 1 to 10 carbon atoms. Optionally the titanate may contain partially unsaturated groups. However, preferred examples of R include but are not restricted to methyl, ethyl, propyl, isopropyl, butyl, tertiary butyl and a branched secondary alkyl group such as 2,4-dimethyl-3-pentyl. Preferably, when each R is the same, R is an isopropyl, branched secondary alkyl group or a tertiary alkyl group, in particular, tertiary butyl.

Alternatively, the titanate may be chelated. The chelation may be with any suitable chelating agent such as an alkyl acetylacetonate such as methyl or ethylacetylacetonate. Examples of suitable titanium and/or zirconium based catalysts are described in EP 1254192 which is incorporated herein by reference. The amount of catalyst used depends on the cure system being used but typically is from 0.01 to 3% by weight of the total composition

The catalyst chosen for inclusion depends upon the speed of cure required. When the cross-linker of (C)(iii) are oximosilanes or acetoxysilanes a tin catalyst is generally used for curing, especially diorganotin dicarboxylate compounds such as dibutyltin dilaurate, dibutyltin diacetate, dimethyltin bisneodecanoate. For compositions which include alkoxysilane cross linker compounds, the preferred curing catalysts are titanate or zirconate compounds such as tetrabutyl titanate, tetraisopropyl titanate, or chelated titanates or zirconates such as for example diisopropyl bis(acetylacetonyl)titanate, diisopropyl bis(ethylacetoacetonyl)titanate, diisopropoxytitanium Bis(Ethylacetoacetate) and the like.

The cross linker used in (C)(iii) is preferably a silane compound containing hydrolysable groups. These include one or more silanes or siloxanes which contain silicon bonded hydrolysable groups such as acyloxy groups (for example, acetoxy, octanoyloxy, and benzoyloxy groups); ketoximino groups (for example dimethyl ketoximo, and isobutylketoximino); alkoxy groups (for example methoxy, ethoxy, and propoxy) and alkenyloxy groups (for example isopropenyloxy and 1-ethyl-2-methylvinyloxy).

In the case of siloxanes the molecular structure can be straight chained, branched, or cyclic.

The cross linker may have two but preferably has three or more silicon-bonded hydrolysable groups per molecule. When the cross linker is a silane and when the silane has three silicon-bonded hydrolysable groups per molecule, the fourth group is suitably a non-hydrolysable silicon-bonded organic group. These silicon-bonded organic groups are suitably hydrocarbyl groups which are optionally substituted by halogen such as fluorine and chlorine. Examples of such fourth groups include alkyl groups (for example methyl, ethyl, propyl, and butyl); cycloalkyl groups (for example cyclopentyl and cyclohexyl); alkenyl groups (for example vinyl and allyl); aryl groups (for example phenyl, and tolyl); aralkyl groups (for example 2-phenylethyl) and groups obtained by replacing all or part of the hydrogen in the preceding organic groups with halogen. Preferably however, the fourth silicon-bonded organic groups is methyl.

Silanes and siloxanes which can be used as cross linkers in condensation cure systems include alkyltrialkoxysilanes such as methyltrimethoxysilane (MTM) and methyltriethoxysilane, alkenyltrialkoxy silanes such as vinyltrimethoxysilane and vinyltriethoxysilane, isobutyltrimethoxysilane (iBTM). Other suitable silanes include ethyltrimethoxysilane, vinyltriethoxysilane, phenyltrimethoxysilane, alkenyl alkyl dialkoxysilanes such as vinyl methyl dimethoxysilane, vinyl ethyldimethoxysilane, vinyl methyldiethoxysilane, vinylethyldiethoxysilane, alkenylalkyldioximosilanes such as vinyl methyl dioximosilane, vinyl ethyldioximosilane, vinyl methyldioximosilane, vinylethyldioximosilane, alkoxytrioximosilane, alkenyltrioximosilane, alkenylalkyldiacetoxysilanes such as vinyl methyl diacetoxysilane, vinyl ethyldiacetoxysilane, vinyl methyldiacetoxysilane, vinylethyldiacetoxysilane and alkenylalkyldihydroxysilanes such as vinyl methyl dihydroxysilane, vinyl ethyldihydroxysilane, vinyl methyldihydroxysilane, vinylethyldihydroxysilane, methylphenyl-dimethoxysilane, 3,3,3-trifluoropropyltrimethoxysilane, methyltriacetoxysilane, vinyltriacetoxysilane, ethyl triacetoxysilane, di-butoxy diacetoxysilane, phenyl-tripropionoxysilane, methyltris(methylethylketoximo)silane, vinyl-tris-methylethylketoximo)silane, methyltris(methylethylketoximino)silane, methyltris(isopropenoxy)silane, vinyltris(isopropenoxy)silane, ethylpolysilicate, n-propylorthosilicate, ethylorthosilicate, dimethyltetraacetoxydisiloxane. Further alternative cross-linkers include Alkylalkenylbis(N-alkylacetamido) silanes such as methylvinyldi-(N-methylacetamido)silane, and methylvinyldi-(N-ethylacetamido)silane; dialkylbis(N-arylacetamido) silanes such as dimethyldi-(N-methylacetamido)silane; and dimethyldi-(N-ethylacetamido)silane; Alkylalkenylbis(N-arylacetamido) silanes such as methylvinyldi(N-phenylacetamido)silane and dialkylbis(N-arylacetamido) silanes such as dimethyldi-(N-phenylacetamido)silane. The cross-linker used may also comprise any combination of two or more of the above.

C(iv) is a cationic initiator which can be used when resin/polymer blends suitable for use as the sheets used in accordance with the present invention contain cycloaliphatic epoxy functionality. These cationic initiators are suitable for thermal and/or UV cure. The preferred resins may be prepared, such that when compounded with iodonium or sulfonium salts will yield a cured network on heating. The initiation temperature of such systems can be controlled by the use of suitable radical initiators. These systems can also be cured by UV-visible irradiation when sensitized with suitable UV-visible radical initiators such those described above as Component (C)(ii). The functionality and catalyst levels can be tuned to initiate cure at high speeds under ambient conditions then effect bonding and final cure in the laminator.

In the case o this embodiment of the invention, most preferably the cure process is selected from either Component (C)(i), and Component (C)(ii) and the polymer and resin comprise unsaturated groups, typically vinyl groups.

A component (D) in the form of small highly functional modifiers such as methyl vinyl cyclic organopolysiloxane structures (Dₓ^{vi}) and branched structures such as (M^{vi}Dₓ)₄Q (as described in EP 1070734, the contents of which are incorporated herein by reference) may optionally be utilised in addition to or instead of some of component (A) when utilizing cure systems (C)(i) and C(ii).

The proportions of components (A), (B) and (C) and any optional ingredients present in the formulation may comprise any suitable amounts but the total composition must be a maximum of 100% by weight. When thoroughly mixed together the resulting mixture may be formed, using an extrusion or molding process or the like into a flexible sheet. Each sheet may be uncured or may undergo partial cure prior to application into a solar cell. Each sheet may also be supported between one or two release liners. The release liners should be suitably coated to afford easy release of the liner from the silicone sheet.

The encapsulant used in this embodiment of the present invention may comprise any one of the cure systems (C)(i) to (C)(iv) defined above or combination thereof. There are different advantages and disadvantages with each cure system, for example faster more controlled and cleaner cure can be achieved by using non-peroxide cure systems such as condensation or hydrosilylation reactions. Furthermore process times, in particular Laminator cycle time can be reduced by >20% or the laminator could be completely eliminated when using cure systems as described above when compared to encapsulation with peroxide EVA or the like.

It is preferred to disperse component (B) in a suitable amount of component (A) or a solvent to ensure ease of mixing with bulk of component (A). Any suitable solvents may be used such as for example aromatic solvents such as toluene and xylene, ketones such as methyl isobutyl ketone, alcohols such as isopropanol and non-aromatic cyclic solvents such as hexane. Typically, when a solvent is used, xylene is preferred.

As an alternative to undergoing partial cure during mixing, co-reactive silicone polymer and resins suitable for use in accordance with the present invention may be pre-reacted (or tethered) together to form curable polymer-resin networks which may be subsequently formed into suitable sheets. This process is sometimes referred to in the industry as bodying. One significant advantage in forming a curable resin-polymer network into sheets in accordance with the present invention is that a wider range of resin-polymer compositions can be used when the constituent resins and polymers are chemically pre-reacted (tethered). Chemical tethering the constituent resin/s and polymer/s results in a reduction of surface tack at lower resin loading levels leads to more flexible and less brittle encapsulants being prepared. Materials suitable for use in photovoltaic applications can be prepared by “bodying” silanol functional polymers with silanol functional resins. The bodying reaction which is a complex process involving condensation and re-organization, can be carried out using base or acid catalysis. The process can be further refined by the inclusion of reactive or non-reactive organo-silane species, as outlined in EP 1083195 the contents of which are incorporated herein by reference. These systems can also be tailored to include the command cure process outlined above.

In accordance with a second embodiment of the present invention the organopolysiloxane based (silicone) hot melt sheets suitable for use in the present invention may alternatively be prepared from block copolymers commonly described as thermoplastic elastomers having a “hard” segment (having a glass transition point T_{g}≧ the operating temperature of the photovoltaic cell module in accordance with the present invention) and a “soft” segment (having a glass transition point T_{g}≦ the operating temperature of the photovoltaic cell module in accordance with the present invention). In the present invention the soft segment is an organopolysiloxane segment. Silicones possess excellent thermal, UV, weather stability and excellent water vapor permeability. However, silicones lack some of the mechanical strength exhibited by many organic polymers. An important way to improve the mechanical strength while retaining the desired properties of siloxanes is via the controlled synthesis of AB and ABA or (AB)n block copolymer.

The use of such a thermoplastic elastomer in this embodiment of the present invention results in lower melt temperature and viscosity along with better rubber properties.

Preferably the sheets of thermoplastic silicon copolymers are prepared from:—

(i) a hard segment polymer constituent prepared from an organic monomer or oligomer or combination of organic monomers and/or oligomers such as but not restricted to styrene, methylmethacrylate, butylacrylate, acrylonitrile, alkenyl monomers, isocyanate monomers; and

(ii) a soft segment polymer constituent prepared from a compound having at least one silicon atom typically an organopolysiloxane polymer, preferably of the type as hereinbefore described.

Each of the above mentioned hard and soft segments can be linear or branched polymer networks or combination thereof. Copolymers can be prepared using polymerization of monomers or prepolymers/oligomers. For the sake of this invention such material can be prepared as a transparent sheet form useful for photovoltaic cell encapsulation.

One preferred copolymer for use in this embodiment of the present invention are Silicone-urethane and silicone-urea copolymers. Silicone-urethane and silicone-urea copolymers (U.S. Pat. No. 4,840,796, U.S. Pat. No. 4,686,137) have been known to give materials with good mechanical properties such as being elastomeric at room temperature. Desired properties of silicone-urea/urethane copolymers can be obtained by varying the level of polydimethylsiloxane (PDMS), the type of chain extenders used and type of isocyanate used.

The most common way for synthesizing silicone urea or urethane copolymers involves the reaction of silicone functional diamine or diol with excess diisocyanate to form urea or urethane group, respectively. The resulting linear polymer is reacted with short chain diol or diamine as chain extenders.

Among the isocyanates used to synthesize urethane or urea copolymers cyclic aliphatic diisocyanates provide major advantages due to its UV and superior weather resistance.

Silicone-urethane/urea(s) copolymers are transparent elastomeric material with excellent light transmission. To our knowledge we aren't aware of using silicone-urethane/ureas(s) as encapsulant for photovoltaic cells. Due to its excellent light transmission and excellent weather resistance these copolymers are useful as encapsulant for the light facing side of photovoltaic cell.

In systems where it is deemed necessary to achieve a two-stage cure or where adhesion dictates, the aforementioned systems can be combined. Radical initiation and transition metal catalyzed addition has been demonstrated in the past. The advantage of such dual cured systems lies in rapidly developing a degree of cure sufficient to allow further handling and photovoltaic fabrication, with continued cure and adhesion building out side the curing apparatus. Of particular utility is the formation of a thermally initiated green state such that the device can be removed from a laminator and continue down the assembly process, developing full cure and adhesion a predetermined time later under ambient conditions. Such systems reduce the thermal stress experienced by the photovoltaic wafers and panels which lead to manufacturing waste and provide for initial reworkability and good long term stability. Furthermore, the time required for the lamination step can be greatly reduced. Alternatively, the batch wise lamination process could be replaced by a heated pinch roller to provide a cost effective continuous process.

Preferably the copolymers as hereinbefore described are reactive and as such curable using one of the cure systems as hereinbefore described. The copolymers may be utilised alone but are preferably cured with a cure system as hereinbefore described. Where appropriate silicone resins as hereinbefore described may be added to the copolymers but typically this will not be necessary.

Optionally the polymer resin blends, resin polymer networks and copolymers detailed above may be used in combination with variety of additives such as fillers, extending fillers, pigments, adhesion promoters, corrosion inhibitors, dyes, diluents, etc. Such additives are chosen with suitable experimentation to avoid adverse effects on shelf-life, cure kinetics and optical properties.

The hot melt material may additionally comprise one or more fillers to reduce weight and lower cost and to change color or reflectivity. These may comprise one or more finely divided, reinforcing fillers such as high surface area fumed and precipitated silicas and to a degree calcium carbonate as discussed above, or additional extending fillers such as crushed quartz, diatomaceous earths, barium sulphate, iron oxide, titanium dioxide and carbon black, talc, wollastonite. Other fillers which might be used alone or in addition to the above include aluminite, calcium sulphate (anhydrite), gypsum, calcium sulphate, magnesium carbonate, clays such as kaolin, aluminium trihydroxide, magnesium hydroxide (brucite), graphite, copper carbonate, e.g. malachite, nickel carbonate, e.g. zarachite, barium carbonate, e.g. witherite and/or strontium carbonate e.g. strontianite. Alternatively, low density fillers may be used to reduce weight and cost per volume.

Aluminium oxide, silicates from the group consisting of olivine group; garnet group; aluminosilicates; ring silicates; chain silicates; and sheet silicates. The olivine group comprises silicate minerals, such as but not limited to, forsterite and Mg₂SiO₄. The garnet group comprises ground silicate minerals, such as but not limited to, pyrope; Mg₃Al₂Si₃O₁₂; grossular; and Ca₂Al₂Si₃O₁₂. Aluninosilicates comprise ground silicate minerals, such as but not limited to, sillimanite; Al₂SiO₅; mullite; 3Al₂O₃.2SiO₂; kyanite; and Al₂SiO₅

The ring silicates group comprises silicate minerals, such as but not limited to, cordierite and Al₃(Mg,Fe)₂[Si₄AlO₁₈]. The chain silicates group comprises ground silicate minerals, such as but not limited to, wollastonite and Ca[SiO₃].

The sheet silicates group comprises silicate minerals, such as but not limited to, mica; K₂AI₁₄[Si₆Al₂O₂₀](OH)₄; pyrophyllite; Al₄[Si₄O₂₀](OH)₄; talc; Mg₆[Si₈O₂₀](OH)₄; serpentine for example, asbestos; Kaolinite; Al₄[Si₄O₁₀](OH)₈; and vermiculite.

In addition, a surface treatment of the filler(s) may be performed, for example with a fatty acid or a fatty acid ester such as a stearate, or with organosilanes, organosiloxanes, or organosilazanes hexaalkyl disilazane or short chain siloxane diols to render the filler(s) hydrophobic and therefore easier to handle and obtain a homogeneous mixture with the other sealant components The surface treatment of the fillers makes the ground silicate minerals easily wetted by the silicone polymer. These surface modified fillers do not clump, and can be homogeneously incorporated into the silicone polymer. This results in improved room temperature mechanical properties of the uncured compositions. Furthermore, the surface treated fillers give a lower electrical conductivity than untreated or raw material.

The use of a heat conducting filler is particularly advantageous when the substrate is also thermally conductive thus enabling the removal of excess heat from the photovoltaic cells which improves cell efficiency.

Suitable fillers for use in the sheets required to be transparent to light need to substantially match the refractive index of the silicone or be dispersed particles smaller than ¼ the wavelength of light to avoid scattering the light. Hence, fillers such as wollastonite, silica, titanium dioxide, glass fibre, hollow glass spheres and clays e.g. kaolin are particularly preferred.

The proportion of such fillers when employed will depend on the properties desired in the elastomer-forming composition and the cured elastomer. Usually the filler content of the composition will reside within the range from about 5 to about 150 parts by weight per 100 parts by weight of the polymer excluding the diluent portion.

Other ingredients which may be included in the compositions include but are not restricted to co-catalysts for accelerating the cure of the composition such as metal salts of carboxylic acids and amines; optical brighteners (capable of absorbing solar energy at the lower wavelengths (200-500 nm) and re-emitting at higher wavelengths (600-900) where the cells are more efficient to increase utilization of all wavelengths of the solar spectrum) rheological modifiers; Adhesion promoters, pigments, Heat stabilizers, Flame retardants, UV stabilizers, Chain extenders, electrically and/or heat conductive fillers, plasticisers, extenders, Fungicides and/or biocides and the like (which may suitably by present in an amount of from 0 to 0.3% by weight), water scavengers, (typically the same compounds as those used as cross-linkers or silazanes) and pre-cured silicone and/or organic rubber particles to improved ductility and maintain low surface tack.

Where required one or more adhesion promoters may also be used to enhance the adhesion of the encapsulant to a superstrate and/or substrate surface. Any suitable adhesion promoter may be utilised. Examples include

vinyltriethoxysilane,
acrylopropyltrimethoxysilane,
alkylacrylopropyltrimethoxysilane

### Allyltriethoxysilane,

glycidopropyltrimethoxysilane,
allylglycidylether
hydroxydialkyl silyl terminated methylvinylsiloxane-dimethylsiloxane copolymer, reaction product of hydroxydialkyl silyl terminated methylvinylsiloxane-dimethylsiloxane copolymer with glycidopropyltrimethoxysilane; and,
bis-triethoxysilyl ethylene glycol (reaction product of triethoxysilane with ethylene glycol).

Preferred adhesion promoters are
i) hydroxydialkyl silyl terminated methylvinylsiloxane-dimethylsiloxane copolymer,
ii) reaction product of hydroxydialkyl silyl terminated methylvinylsiloxane-dimethylsiloxane copolymer with glycidopropyltrimethoxysilane; and
iii) bis-triethoxysilyl ethylene glycol
iv) a 0.5:1 to 1:2, preferably about 1:1, mixture of (i) and a methacrylopropyltrimethoxysilane

Anti-soiling additives may be utilised, where required to prevent soiling when the photovoltaic cells are in use, particularly preferred are fluoroalkene or a fluorosilicone additives that has a viscosity of 10000 mPa·s such as:—fluorinated silsesquixoanes, e.g. dimethylhydrogensiloxy terminated trifluoropropyl silsesquioxane,

hydroxy-terminated trifluoropropylmethyl siloxane,
hydroxy-terminated trifluoropropylmethylsilyl methylvinylsilyl siloxane,

### 3,3,4,4,5,5,6,6,7,7,8,8,8-Tridecafluorooctyltriethoxysilane,

hydroxy-terminated methylvinyl, trifluoropropylsilaxane, and dimethylhydrogensiloxy-terminated dimethyl trifluoropropylmethyl siloxane

Preferably, the anti-soiling additive is present in an amount of from 0 to 5 parts by weight, more preferably 0 to 2 parts by weight and most preferably 0 to 1.5 parts by weight. Preferably when the encapsulant is used both in the absence of the adhesive layer referred to below the anti-soiling additive is included in the encapsulant composition as well as when used in combination with the adhesive layer.

Other additives that enhance the physical properties may be utilised in the composition. One particular example is the inclusion of a fire retardant. Any suitable fire retardant or mixture of fire retardants may be used providing they do not negatively affecting the other physical properties of the encapsulant composition. Examples include alumina powder, or wollastonite as described in WO 00/46817. The latter may be used alone or in combination with other fire retardants or a pigment such as titanium dioxide. In cases where the encapsulant need not be transparent to light, it may comprise a pigment.

Prior to preparation of the sheets the composition may be stored in any suitable combination but is preferably a one part or two part system.

Encapsulation in accordance with the present invention may be carried out using any suitable method. The current standard industry process generally utilizes an EVA (ethyl vinyl acetate) thermoplastic encapsulant and a laminatable substrate (sometimes referred to as backing material) such polyester/Tedlar® and the cell or array of cells/module is prepared using a lamination technique. Typically, a suitable laminator is used to laminate the following “sandwich” of layers.

1) Glass superstrate,

### 2) EVA,

3) photovoltaic cell series,

### 4) EVA, and

5) Substrate in the form of a suitable backing material

The standard process uses the laminator apparatus to melt the layers of the “sandwich” at a temperature in the region of 140° C. (actual temperature used is determined in view of the actual composition being laminated) under vacuum for about 20 minutes per module. After lamination and the removal of waste material, surplus to requirements, the next step of the batch process is usually the application of a protective seal which is provided to cover the edges of the module, followed by the framing of the module within a perimeter frame, typically made of aluminium or a plastic material. The overall operation is carried out in a batch mode and is typically slow and very labour intensive.

In one aspect of the present invention, there is provided a process for encapsulating a photovoltaic cell comprising the steps of laminating the following “sandwich” of layers.
1) superstrate,
2) flexible silicone sheet in accordance with the present invention,
3) photovoltaic cell (series),
4) top sheet of suitable encapsulating material, preferably a flexible silicone sheet in accordance with the present invention, and optionally
5) Substrate in the form of a suitable backing material

It is an essential feature of the present invention that the flexible silicone sheet (2) in accordance with the present invention exhibits hot melt characteristics in that at room temperature it is in the form of a flexible sheet, whereas when placed in a laminator application of heat will result in the “melting” of the sheet so as (in the case of (2) above) to act as an adhesive between the superstrate and the photovoltaic cell(s). In the case of partially cured or uncured flexible silicone sheets of the present invention typically application of heat by a laminator or other suitable heating means initiates or re-initiates the cure process. Hence upon cooling the resulting module has an initial green strength from the rigidifying of the encapsulating sheets and will cure using one of the cure processes described above. In one embodiment in accordance with the method of the present invention encapsulation is undertaken via a lamination process.

Preferably (4) above is also a flexible silicone sheet in accordance with the present invention which may be of the same composition as sheet (2), however as discussed above whilst sheet (2) has to be transparent to light sheet (4) need not and therefore may be strengthened by incorporation of fillers therein. Whilst sheet (4) may be different it is preferably of a similar nature to sheet (2) to promote adhesion between the two layers during lamination so as to result in good inter-lamination between sheets (2) and (4). When sheet (4) is filled, the additional strength provided by filler can render the substrate (5) redundant.

When cure speed is properly tuned, the laminator process can be avoided entirely. Instead a heated pinch roller process could be used to assemble and reflow the various layers. Cure would then proceed down stream from the pinch roller.

Preferably the sheets are prepared in a multi step process in which first a Resin/Polymer Blend is prepared by mixing same along a suitable extruder. It is preferred that the resin is introduced onto the extruder in the form of a solution in a suitable solvent (such as xylene) and the solvent is then stripped out subsequent to mixing. Optionally in a one step process the catalyst system, if required may be introduced into the resin stream prior to its introduction into the extruder but preferably catalyst and any other optional ingredient (e.g. diluents, adhesion promoters or curing packages) are introduced into the extruder by means of any suitable method of introduction at an appropriate point along the twin screw barrel. Mixing may take place at any suitable temperature up to about 200° C. and is typically dependent on the cure system being utilised. The gum may be introduced into the extruder by any suitable method but use of a screw conveyor or the like is preferred in view of the viscosity of the gum. The ratio of resin to gum is typically from 1:1 to 9:1 more preferred is a range of from 1:1 to 4:1. A most preferred ratio is between 2:1 and 3:1. If catalyst is introduced into the composition during this extrusion phase the resulting product will be partially cured thereby enhancing the strength of the resulting sheets in due course.

Preferably the resulting stripped material may be extruded and processed into pellets with a cooling step prior to pelletising if required. The resulting blend may be subsequently packaged in any suitable way.

In a preferred multi step process catalyst system is introduced into the composition subsequent to preparation of the gum/resin blend. This may be achieved in any suitable fashion for example a suitable amount of gum resin blend may be mixed with catalyst. Cross-linker (where required) and other optional ingredients such as for example adhesion promoters and/or fillers. This mixing step may be carried out using any suitable mixer and/or extruder or the like. Subsequent to the introduction of catalyst etc. composition is preferably pressed into sheets and/or rolls (e.g. using a platen press) to form a film having a thickness of at least 5 mm, preferably at least 15 mm thick. Such films may be protected using suitable release liners prior to use.

In the case where the gum/resin blend has been pelletised, rolls of sheet material may be prepared as follows:

The pellets are gravimetrically fed into a single or twin screw extruder. A single screw extruder is preferred to achieve the desired back pressure into the sheeting die. The screw speed and barrel cooling are such to maintain a temperature below the boiling point or reaction temperature of all the ingredients, preferably less than 110° C. A vacuum de-airing section may be utilised to ensure void free films. The extruder feeds a sheeting die via a manifold at high pressure to maintain a uniform sheet profile with good production speed. The typical sheeting die provides for a 5 to 50 mils (0.127 to 1.27 mm) thick sheet of any suitable width up to approximately 6 feet (1.83 m) wide. The preferred width is 15-20 mils (0.381 to 0.508 mm) thick and 4 feet (1.22 m) wide. The sheet is cooled on a cold roll to solidify the hot melt an optional release liner is fed into the take up roll providing for a continuous roll of hot melt sheet. Suitable release liners consist of wax coated paper, polypropylene film, fluoropolymer films with our without release coatings. Whilst a release liner is not essential preferably one or both sides of the hot melt sheet produced continuously in this manner is protected with a release liner. The resulting sheets may be prepared on a continuous roll or cut and stacked to specific width and length requirements as determined by their end use.

The resulting hot melt sheet(s) may be further processed to impart for example a dimpled surface as is common among EVA suppliers. The provision of dimpling on the sheets is intended to reduce problems caused by surface tack and aids in air removal during encapsulation (lamination in the case of using EVA).

In still further method of preparation the hot melt sheets in accordance with the present invention may be prepared by casting from solvent onto a continuous release liner, but this process is not preferred.

The use of such an organopolysiloxane based hot melt material provides the advantages of more efficient manufacturing and better utilization of the solar spectrum by using silicone hot melt sheets to give a silicone encapsulant photovoltaic device with the process ease of an organic encapsulant but the optical and chemical advantages of a silicone encapsulant. Additional advantages include:—

i. Silicone based encapsulants are UV transparent and may increase cell efficiency by at least 1-5%;

ii. Peroxide cured silicone based compositions provide better transparency and similar cure speed relative to EVA;

iii. Silicone based sheet encapsulant have more efficient cell assembly as compared to liquid silicone encapsulants;

iv. Faster more controlled and cleaner cure can be achieved by using non-peroxide cure systems such as condensation or hydrosilylation reactions. Laminator cycle time can be reduced by >20% or the laminator could be completely eliminated.

The invention will now be described by way of example and with reference to the following Figures and Examples in which

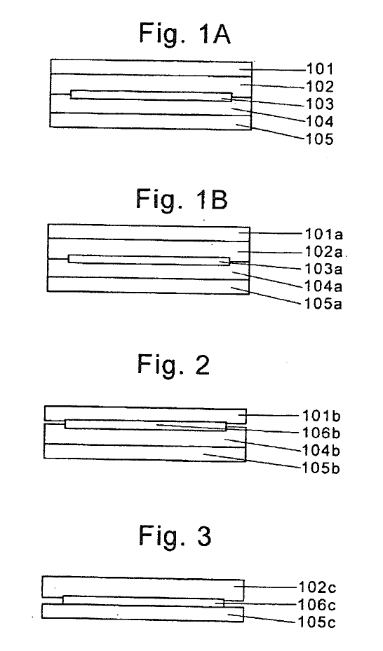

FIGS. 1a and 1b depict an encapsulated photovoltaic cell in accordance with the prior art and with the present invention respectively.

FIGS. 2 and 3 depict alternative encapsulated photovoltaic cell modules in accordance with the present invention respectively

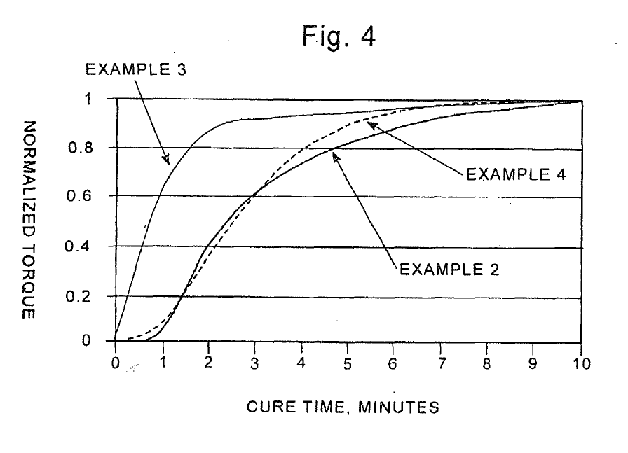

FIG. 4 depicts a graphical study of the cure of the sheet materials; and

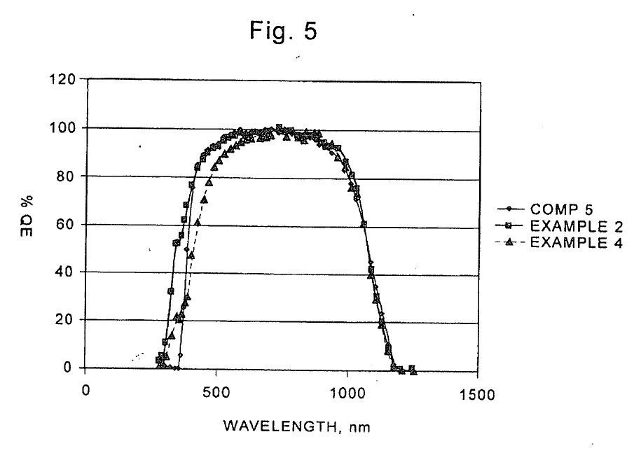

FIG. 5 depicts the cell efficiency for single wafer photovoltaic cells encapsulated using sheets in accordance with the present invention in comparison with an EVA encapsulated cell.

FIG. 1a is intended to depict the currently most favoured arrangement of layers in a photovoltaic module prior to lamination, the currently preferred process of photovoltaic (PV) module production involving PV wafers. The arrangement, utilizes multiple sheets of EVA 102 and 104 as the hot melt thermoset adhesive to bond and encapsulate Si-wafers 103 to a glass superstrate (front plate) 101 and Tedlar or PET/Siox-PET/Al substrate (back sheet) 105. The superstrate 101 whilst transparent to light is made from a suitable glass which typically must be doped with a suitable dopant to filter UV light. A preferred dopant is cerium. However, dopants are not needed because encapsulants in accordance with the present invention have superior UV stability because of their silicone content.

As depicted in FIG. 1b in accordance with the present invention front sheet encapsulant 102a mainly functions as the means of adhering the PV cells to glass superstrate 101a. Typically front sheet encapsulant 102a in accordance with the present invention will be a blend of silicon resin with siloxane gum and/or silicone fluid or alternatively the silicone-organic block copolymer as hereinbefore described. Preferably encapsulant 102a is in an uncured state prior to use but may be partly cured by way of any of cure systems discussed previously prior to use. Further cure may occur during production of the resulting laminate above. A key feature of this layer is that it is produced in a solid sheet form with minimal tack or flow at room temperature but will flow on heating to wet and adhere to the superstrate (glass) 101a and the Silicon wafer/PV cell 103a as well as to a second silicone sheet 104a. Sheet 102a will show high transmission across visible wavelengths, long term stability to UV and provide long term protection to the PV cell 103a. Unlike in the prior art embodiment depicted in FIG. 1a, typically there is no need for the superstrate, used in accordance with the present invention, to be doped with a dopant such as cerium because the hot melt sheets used as encapsulants in accordance with the present invention have superior UV stability because of their silicone content.

In the case when the composition comprises a silicone resin, the resin used is preferably of the MQ type and preferably contains alkenyl (typically vinyl) functionality. The polymer (i.e. silicone gum or fluid) is substantially linear and may contain vinyl functionality for cross linking and other functionality such as hydroxy or other hydrolysable groups and potentially Si H and/or epoxy type groups to promote adhesion. Within the sheets 102a appropriate fillers may be incorporated in the formulation, such as glass fibre or glass beads, these would need to be refractive index (RI) matched to maintain transmission. It is possible that this could include Platinum to maintain clarity whilst providing a degree of flame redundancy. It is also possible that an optical brightener may be added to further increase cell efficiency.

The resulting sheets 102a in accordance with the present invention:—

are tack free” to allow manipulation during application (lay up);
are sufficient in mechanical strength so as not to stretch or break during application (lay up); offer high clarity and transmission
flow during the encapsulation process (e.g. lamination) to wet and seal all parts; and
is adapted to adhere to all other components

Back sheet encapsulant 104a has a similar composition to sheet 102a and generally functions as an intermediate layer between layer 102a, cells 103a and the optional substrate present 105a. Back sheet encapsulant 104a functions as the substrate in the absence of optional layer 105a. Silicone sheet 104a need not have a refractive index approaching that of glass as it does not function as a means of transmitting light to the PV cells and as such may additionally comprise fillers which will have a negative effect on its refractive index, preferred examples include wollastonite, silica, TiO₂, glass fiber, hollow glass spheres, clays These fillers will provide flame retardancy, additional mechanical strength and reduced cost. Again material will be provided in sheet form with minimal flow at room temperature but will flow on heating. As an alternative each sheet 104a this may be uncured, partially cured or fully cured prior to use. Layer 104a may alternatively be applied in a liquid form in accordance with the applicants co-pending application WO 2005/006451, which is incorporated herein by reference.

The presence of a substrate 105a is optional and the need for a substrate is determined dependent on the required mechanical properties of the back sheet encapsulant and the requirements of the module as a whole. A still further layer may be used to provide additional protection to the back of the cell. This could be polyester, polyolefin or similar. It is also possible that 104a could be used as a carrier for 103a during the process to aid handling and be left in place during use. As an alternative 105a could be a cured HCR or LSR sheet whilst 104a has a similar composition to 102a and acts to provide adhesion between 104a and the PV cell and to sheet 102a.

Hence In the preferred embodiment of the present invention:

The superstrate, 101a, is typically UV transparent glass.
Sheet 102a is a silicone sheet in accordance with the present invention.
The PV cell is depicted as 103a and typically is made from poly or monocrystalline silicon wafers
104a is a second silicone sheet in accordance with the present invention; and The substrate 105a is not needed.

As depicted in FIG. 2 there is provided an alternative embodiment of the present invention a PV module based on thin film PV's can also be envisioned where the thin film PV cell (106b) is applied to a transparent superstrate and 101b, 104b and 105b are the same as 101a, 104a and 105a respectively above. Typically in this case however, the thin film PV cell 106 is deposited on the glass by a suitable method such as chemical vapor deposition after which a flexible sheet of silicone material in accordance with the present invention is applied.

In a still further embodiment as shown in FIG. 3 PV modules based on thin film PV cells can also be envisioned where the thin film PV cell 106c is applied to a non-transparent substrate 105c. In FIG. 3 sheet 102c is a flexible sheet of silicone material in accordance with the present invention which also functions as the PV cell superstrate. In this case the thin film cell is deposited on the substrate in a manner as hereinbefore described. A superstrate of for example glass or a suitable fluorocarbon sheet. (not shown may be utilised if required).

### EXAMPLES

### Example 1

### Preparation of a Resin/Polymer Blend

A trimethyl terminated poly dimethyl, methyl vinyl siloxane gum having a plasticity of 58 mils as measured by ASTM 926 was blended with a solution of 30% by weight vinyl functional MQ resin in xylene in a ZSK dual lobed twin screw extruder using the following process:—The M:Q resin had an M:Q ratio of approximately 0.75, a vinyl content of approximately 1.8 wt % and number average molecular weight of 6000 g/mole. The trimethyl terminated poly dimethyl, methyl vinyl siloxane gum was fed into the extruder using a single screw feeder and the resin solution was introduced using a positive displacement feed pump, initial mixing took place at a temperature of approximately 150° C. and after a period of 1 minute the temperature was increased to 180° C. to complete the mixing process and in order to strip out the xylene. Three vacuum stripping zones, each at a pressure of 29″ Hg (98.2 kNm⁻²) were utilized to achieve solvent removal of greater than 99%. The resulting gum/resin blend was extruded through a ¼ inch (0.635 cm) diameter die and subsequently transported through a cooling zone and into a pelletizer adapted to prepare ⅛ inch (0.32 cm) long pellets. The pellets were then packaged into plastic bags.

The gum/resin blend prepared in Example 1 was metered in order to produce a final composition containing 28% gum and 72% resin and a final vinyl content of 1 wt %.

### Example 2

### Addition of Catalyst to the Resin Gum Blend

To introduce a catalyst package into the product of example 1 above, 95.5% by weight of the product of Example 1 was mixed with 3% by weight of 1,1-bis(tert-butylperoxy)3,3,5-trimethylcyclohexane and 1% by weight of a vinyl functional cross linker in the form of a linear polydimethylsiloxane with degree of polymerization 100 and vinyl content of 0.05% by weight and 0.5% of an acrylylpropyltrimethoxy silane functional adhesion promoter in a Haake mixer equipped with sigma blades and preheated to 110° C. The resulting product was pressed into a sheet using a platen press under a force of 300 kN to give a clear film of about 25 mil (0.635 mm) thickness. Silicone coated polyester was used as a release liner to prevent adhesion of the product to the press.

### Example 3

In Example 3 93.4% by weight of gum/resin blended pellets prepared as described in Example 1, was introduced into a Haake mixer equipped with sigma blades and preheated to 110° C. To this was added 6.13% by weight methyl hydrogen cyclic siloxane with average ring size of 4.5 repeat units. Subsequent to mixing, at approximately 110° C. the resulting mixture was allowed to cool to 70° C. whilst mixing was continued. Finally 0.28% by weight diallyl maleate catalyst inhibitor and a homogenous Pt complex 0.19 by weight was introduced into the mixture. The resulting homogenous mixture was pressed between 2 sheets of fluoro-coated PET to a thickness of 15 mils (0.381 mm), and cured under glass in a laminator within 7 minutes at a 150° C. set temperature.

### Example 4

In example 4 the hot melt sheet in accordance with the present invention comprises a polysilicone block urea with polydimethylsiloxane blocks of 40 repeat units and urea blocks of 3 repeat units. In a 3 litre three-neck round bottomed flask equipped with magnetic stirrer, thermometer, nitrogen inlet and condenser was charged with 8.6 g of Bis(4-isocyanatocyclohexyl)Methane (HMDI) and 300 mL of dry tetrahydrofuran (Aldrich), the mixture was stirred and a 100 g of aminopropyl terminated siloxane (DMS-A15, Gelest) was added. The reaction mixture was heated at 70° C. for 2 hours. The reaction was followed by IR. After the disappearances of the isocyanate peak at 2264 cm⁻¹ the resulting, mixture was poured on to a liner and solvent evaporated to obtain transparent sheet. The transparent sheet was further pressed to a uniform thickness using a Drake hydraulic press at 100 psi (703×10⁵ gm⁻²) and 80° C. for 30 minutes. The resulting transparent thermoplastic elastomer having a tack free surface and softening point of approximately 80° C.

As a means of comparison with current industry standards the results of the above were compared with a Comparative example 5 in the form of a peroxide cured EVA encapsulant material typical of those currently commercially available for the encapsulation of photovoltaic cells by lamination.

### Cure of Catalysed Resin Gum Blends

The rate of cure of examples 2 and 3 were compared with comparative example 5 using a moving die rheometer (MDR)(Monsanto 2000E) which is a standard tool for following the cure of rubber samples. The die temperature was 150° C. All the results were normalized by dividing the torque by the plateau torque and the results are depicted in FIG. 4. Example 4 was not measured because it was not designed to cure.

The increase in cure speed can easily be noted for example 3 as compared to comparative example 5, while example 2 has a similar cure speed to comparative example 5.

Samples for measurement of light transmission were prepared by laminating sheets of examples 2 and 4 between two pieces of quartz glass. Comparative example 5 was also laminated between two pieces of quartz glass. A UV/visible spectrometer was used to measure the transmission utilizing a single 2.6 mm quartz glass for background subtraction. As expected it was found that example, 2, has an excellent higher transparency over a wider spectrum of light. This can enable more useful light to impinge on the PV surface thus increasing the efficiency of the array. In comparison to example 2 it was found that Example 4 had better transparency in the UV range and similar transparency in the higher wavelengths. Also as expected comparative example 5 did not function at wavelengths shorter than 400 nm.

FIG. 5 depicts the cell efficiency for single wafer photovoltaic cells encapsulated using sheets in accordance with the present invention prepared as depicted in FIG. 2. The cell efficiency was measured using a Spectral Response System filtered light source using a 1-kW xenon arc lamp and 61 narrow-band-pass filters mounted on four wheels. The system was calibrated to determine the beam intensity passed through each filter. The quantum efficiency (QE) profile was normalized to 100% at its maximum for relative units of QE. FIG. 6 contains the quantum efficiency data for examples 2, 4 and comparative example 5. The results shown in FIG. 5 demonstrate that fully functional, good photovoltaic cells are produced using examples 2 and 4. Example 2 had improved QE versus comparative 5. Example 4 was better over short wavelengths

1. A method for fabricating photovoltaic cell modules comprising the steps of
i) bringing at least one sheet of organopolysiloxane based hot melt material into contact with
(a) a photovoltaic cell or an array of photovoltaic cells and/or
(b) a light transparent superstrate;
at room temperature;
ii) heating the combination resulting from step (i) such that the sheet(s) of organopolysiloxane based hot melt material become(s) a liquid of sufficiently low viscosity to adhere to said photovoltaic cell(s) and/or to said superstrate;
iii) allowing the product resulting from step (ii) to cool;
iv) bringing the product of step (iii) into contact with either (a) or (b) when omitted from step (i) and/or optionally a substrate and reheating and cooling to form a photovoltaic cell module.

2. The method of claim 1 wherein Step (iv) takes place during or subsequent to step (iii) at a temperature above room temperature.

3. (canceled)

4. The method of claim 1 wherein one or more sheet(s) of organopolysiloxane based hot melt materials are initially applied to a photovoltaic cell or an array of photovoltaic cells and then the resulting encapsulated photovoltaic cells or array of photovoltaic cells-are applied onto the superstrate.

5. The method of claim 1 wherein one or more sheet(s) of organopolysiloxane based hot melt materials are initially applied on to a superstrate to provide a pre-coating and then a photovoltaic cell or an array of photovoltaic cells are applied on to the pre-coated superstrate.

6. The method of claim 1 wherein a thin film Photovoltaic cell is applied on to a transparent superstrate and one or more sheets of organopolysiloxane based hot melt material are applied thereon.

7. The method of claim 1 wherein one or more sheets of organopolysiloxane based hot melt material function as a superstrate for the photovoltaic cell.

8. The method of claim 1 wherein the hot melt material is a reactive hot melt material.

9. The of claim 1 wherein the hot melt material comprises a blend of a substantially linear organopolysiloxane polymer and a silicone resin which are adapted to cure in the presence of an initiator or catalyst/cross linker system.

10. The method of claim 1 wherein the hot melt material comprises:
(A) A high molecular weight diorganopolysiloxane comprising at least two reactive groups per molecule, which reactive groups are designed to react with component B;
(B) a silicone resin or mixture of resins comprising reactive groups which react with reactive groups on component (A) in the presence of component (C); and
(C) a suitable curing agent which causes the reaction between the reactive groups on components A and B.

11. The method of claim 9 wherein the reactive groups in both components (A) and (B) comprise unsaturated groups and component (C) comprises a hydrosilylation catalyst and a cross-linking agent comprising a polyorganosiloxane having at least two silicon-bonded hydrogen atoms per molecule.

12. The method of claim 9 wherein component (C) is an organic peroxide.

13. The method of claim 1 wherein the hot melt material has been partially cured and/or bodied before step (i).

14. The method of claim 1 wherein the hot melt material comprises one or more thermoplastic block copolymers obtainable by mixing a hard segment comprising a polymer having a glass transition point T_{g}≧ the operating temperature of the photovoltaic cell module and a soft segment comprising an organopolysiloxane polymer having a glass transition point T_{g}≦ the operating temperature of the photovoltaic cell module.

15. The method of claim 13 wherein the thermoplastic block copolymers are selected from the group of silicone-urethane and silicone-urea copolymers.

16. The method of claim 1 wherein the hot melt sheets additionally comprise fillers which substantially match the refractive index of the sheet material and/or dispersed particles of a size smaller than ¼ the wavelength of light selected from one or more of the group of wollastonite, silica, titanium dioxide, glass fibre, hollow glass spheres and clays.

17. The method of claim 1 wherein the hot melt sheets additionally comprise one or more of additives selected from the group consisting of co-catalysts; optical brighteners, rheological modifiers; Adhesion promoters, pigments, Heat stabilizers, Flame retardants, UV stabilizers, Chain extenders, electrically and/or heat conductive fillers, plasticisers, extenders, Fungicides and/or biocides, water scavengers, and pie-cured silicone and/or organic rubber particles.

18. A photovoltaic cell module comprising a photovoltaic cell or an array of photovoltaic cells encapsulated in an organopolysiloxane based hot melt material, said organopolysiloxane based hot melt material being adhered to a light transparent superstrate and optionally a supporting substrate.

19. (canceled)
